(19) United States
(12) Patent Application Publication
(10) Pub. No.: US 2015/0240348 A1
(43) Pub. Date: Aug. 27, 2015

(54) METHOD FOR MANUFACTURING OPTICAL FILTER

(71) Applicant: Koji Hanihara, Yamanashi (JP)

(72) Inventor: Koji Hanihara, Yamanashi (JP)

(21) Appl. No.: 14/423,830

(22) PCT Filed: Aug. 30, 2012
(86) PCT No.: PCT/JP2012/005489

§ 371 Date: Mar. 18, 2015

(51) Int. Cl. C23C 14/34; G02B 5/28

(52) U.S. Cl. CPC C23C 14/34; G02B 5/28

(57) ABSTRACT

The problem addressed by the present invention is easily and by means of a simple configuration to form a filter layer having a different film thickness at each position. The present invention is a method for producing a variable-transmission-wavelength interference filter (16) configuring a plurality of filter units (28), and is characterized by: using a mask member (75) that is interposed between a sputtering target (73) and a light reception element array (15) and that has an aperture ratio that differs at the positions corresponding to each filter unit (28); and causing the vapor phase growth of a dielectric multi-layer film (16a) on the light reception element array (15) with the mask member (75) therebetween.

### TECHNICAL FIELD

The present invention relates to a method for manufacturing an optical filter that includes a filtering layer having different film thicknesses at the respective positions thereof and integrally constitutes a plurality of filtering portions having different transmission characteristics.

### BACKGROUND ART

As such an optical filter, a variable transmission wavelength interference filter has been known in which a filtering layer (multi-layer) is deposited so as to be gradually thicker toward the arrangement direction of light-receiving elements (see Patent Document 1). In addition, as such an optical filter, a variable wavelength interference filter has been known in which a filtering layer (dielectric film) is deposited so as to be gradually thicker toward a circumferential direction on a circular substrate (see Patent Document 2). As a method for manufacturing the filter, Patent Document 2 describes a method including using a circular mask partially opened in the circumferential direction and performing vacuum deposition via the mask while rotating the mask with respect to the circular substrate. According to the manufacturing method, the rotation speed of the mask is varied to control the passing time of the opening at respective positions in the circumferential direction to change the film thickness of the filtering layer at the respective positions in the circumferential direction.

[Patent Document 1] JP-A-11-142752

[Patent Document 2] JP-A-2000-137114

### DISCLOSURE OF THE INVENTION

### Problems that the Invention is to Solve

However, the configuration in which the filtering layer having different film thicknesses at the respective positions thereof is formed using the manufacturing method described in Patent Document 2 requires a driving unit that rotates or moves the mask and a control unit that controls the speed of the mask, which results in the problem that the configuration of a manufacturing apparatus becomes complicated. In addition, there is a problem with the configuration in that the size of the optical filter, which may be manufactured, is limited in terms of structure. Moreover, in such an optical filter, the film thicknesses of respective filtering portions constituting a filtering layer are preferably each uniform (i.e., the respective filtering portions are preferably stepped) as shown in FIG. 2. However, the configuration described above for forming the filtering layer results in the problem that controlling becomes extremely complicated.

The present invention has an object of providing a method for manufacturing an optical filter by which a filtering layer having different film thicknesses at the respective positions thereof can be easily formed with a simple configuration.

### Means for Solving the Problems

The present invention provides a method for manufacturing an optical filter constituting a plurality of filtering portions, the method comprising: using a masking member that is interposed between a source for radiating a vapor deposition material and a workpiece and has different opening ratios at positions thereof corresponding to the respective filtering portions; and vapor-depositing a filtering layer on the workpiece via the masking member.

According to the configuration, the masking member has the different opening ratios at the respective positions thereof. Therefore, the radiated vapor deposition material is shielded at different shielding ratios at the respective positions. This results in a difference in the deposition amount of the vapor deposition material at the respective positions. Therefore, the filtering layer having the different film thicknesses at the respective positions thereof can be formed. Thus, the filtering layer can be formed with the simple configuration free from a driving unit and a control unit. In addition, the filtering layer can be easily formed only by vapor deposition in a state in which the masking member is disposed. Particularly, the filtering layer in which the film thicknesses of the respective filtering portions are each uniform can be easily formed. Therefore, the transmission characteristics of the respective filtering portions can be secured.

In this case, the masking member preferably has a masking main body and a spacer that separates the masking main body and the workpiece from each other, and the filtering layer is preferably vapor-deposited in a state in which the masking member is arranged on the workpiece.

According to the configuration, a specific structure (e.g., supporting member) for disposing the masking member is not required. Therefore, the filtering layer can be formed with the simpler configuration.

In this case, the spacer and the masking main body are preferably made of a SOI wafer.

According to the configuration, the masking member can be easily manufactured by the use of a SOI wafer.

On the other hand, the filtering layer is preferably vapor-deposited by sputtering.

According to the configuration, the filtering layer is formed by sputtering. Therefore, the optical filter with a high degree of precision can be provided.

### BRIEF DESCRIPTION OF THE DRAWINGS

FIG. 1 is a configuration view schematically showing a spectroscope according to an embodiment;

FIG. 2 is a schematic view showing a variable transmission wavelength interference filter;

FIG. 3 shows a determinant for calculating an intensity distribution;

FIGS. 4A to 4C show determinants for calculating a correction matrix;

FIG. 5 is a configuration view schematically showing a filter manufacturing apparatus;

FIG. 6 is a plan view showing a masking member;

FIG. 7 is an explanatory view showing the radiation range of a vapor deposition material radiated from a sputtering target;

FIG. 8A and FIGS. 8B to 8E are a cross-sectional view schematically showing the masking member and cross-sectional views schematically showing a modified example of the masking member, respectively;

FIGS. 9A and 9B are schematic views showing modified examples of the variable transmission wavelength interference filter; and

FIGS. 10A and 10B are plan views showing modified examples of a light-receiving element array.

### DESCRIPTION OF EXEMPLARY EMBODIMENTS

Hereinafter, a description will be given, with reference to the accompanying drawings, of a method for manufacturing an optical filter according to an embodiment of the present invention. The embodiment exemplifies a filter manufacturing apparatus and a manufacturing method for a variable transmission wavelength interference filter to which the present invention is applied. The manufacturing apparatus manufactures the variable transmission wavelength interference filter included in a spectroscope. Therefore, the variable transmission wavelength interference filter and the spectroscope having the variable transmission wavelength interference filter will be described prior to the manufacturing apparatus. The spectroscope represents a small semiconductor package manufactured according to a semiconductor manufacturing technology. In addition, the spectroscope is of a non-mobile type and represents an analysis apparatus that measures the intensity distribution (electromagnetic spectrums of light) of 18 wavelength regions obtained by dividing a visible light region into 18 regions. That is, the spectroscope measures the intensity distribution of the wavelengths of the respective 18 colors of incident light (inspection light).

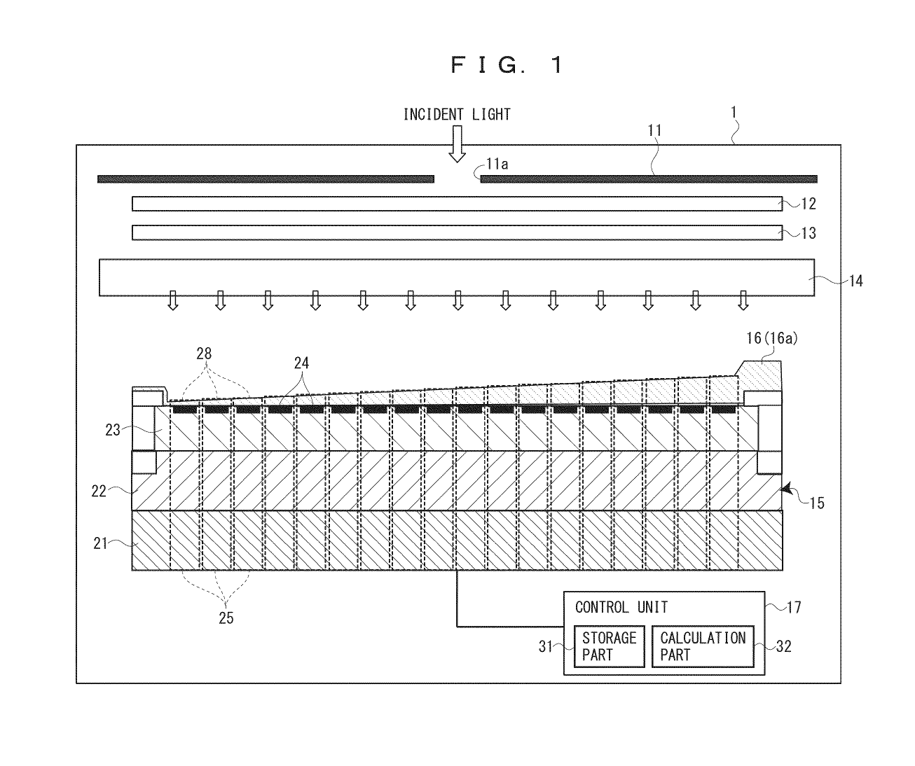

As shown in FIG. 1, a spectroscope 1 includes an incident portion 11 having a light shielding structure that forms an incident opening 11a, a diffusion plate 12 that diffuses incident light from the incident opening 11a, a light guiding plate 13 that deflects the diffused incident light, a collimator lens array 14 that converts the deflected incident light into parallel light, a light-receiving element array 15 constituting 18 light-receiving elements 25 that receive the parallel light, a variable transmission wavelength interference filter (optical filter) 16 formed on the 18 light-receiving elements 25, and a control unit 17 the measures the intensity distribution of respective wavelengths based on the respective output values (photoelectric current values) of the 18 light-receiving elements 25. After being diffused by the diffusion plate 12, the incident light from the incident opening 11a is deflected by the light guiding plate 13 and guided to the 18 light-receiving elements 25 via the collimator lens array 14 and the variable transmission wavelength interference filter 16.

The light-receiving element array 15 is made of a photodiode array and has a P+ substrate 21, a P-EPI layer 22 disposed on the P+ substrate 21, an N-EPI layer 23 formed on the P-EPI layer 22, and a plurality of N+ layers 24 formed side by side on the N-EPI layer 23. Thus, the light-receiving element array 15 constitutes the 18 light-receiving elements (light-receiving portions) corresponding to the N+ layers 24 arranged side by side. The respective light-receiving elements 25 convert the received incident light to obtain photoelectric current values (output values). Then, the respective light-receiving elements 25 output the photoelectric current values to the control unit 17.

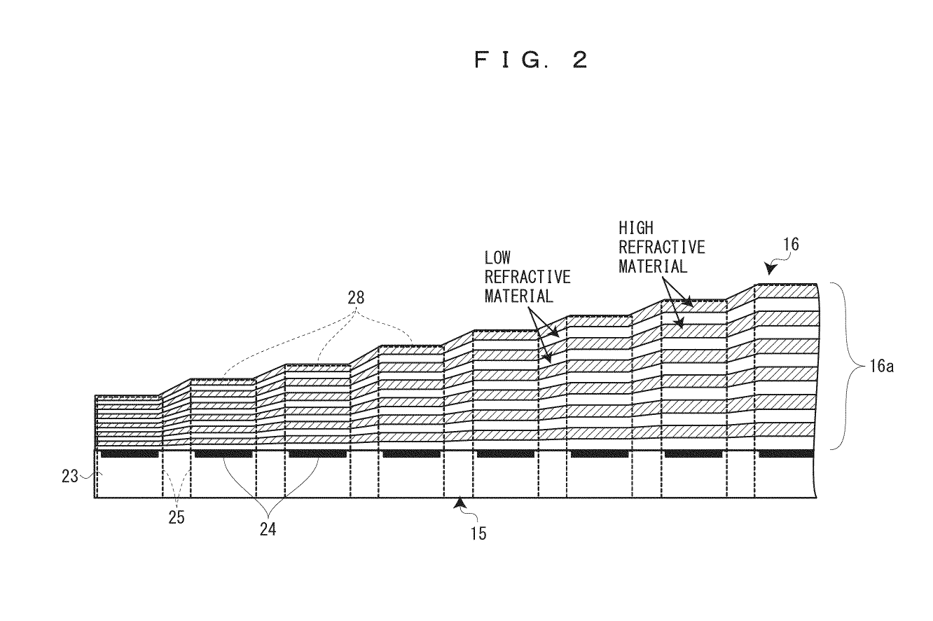

As shown in FIG. 2, the variable transmission wavelength interference filter 16 is made of a dielectric multi-layer film (filtering layer) 16 in which high refractive materials (e.g., TiO₂) and low refractive materials (e.g., SiO₂) are alternately laminated together. The variable transmission wavelength interference filter 16 is such that the dielectric multi-layer film 16a is formed to be gradually thicker toward the arrangement direction of the light-receiving elements 25 and integrally constitutes 18 filtering portions 28 having different transmission peaks. That is, the dielectric multi-layer film 16a is formed such that the film thicknesses of the respective filtering portions 28 are each uniform. The 18 filtering portions 28 correspond to the 18 light-receiving elements 25, respectively, and the light-receiving surfaces of the respective light-receiving elements 25 and the front surfaces of the corresponding respective filtering portions 28 are parallel to each other. Then, the 18 light-receiving elements 25 receive the incident light passing through the 18 filtering portions 28, respectively. In addition, the 18 filtering portions 28 use the respective 18 colors described above as the transmission peaks.

As shown in FIG. 1, the control unit 17 has a storage part 31 that stores a correction matrix and a calculation part 32 that calculates the intensity distribution based on the output values of the respective light-receiving elements 25 and the correction matrix.

The storage part 31 is made of an EPROM (Erasable Programmable Read Only Memory) or the like and stores the correction matrix used to calculate the intensity distribution. The correction matrix is obtained by converting the coefficient matrix of transmission coefficients for the respective filtering portions 28 and the respective colors into an inverse matrix. The correction matrix is generated in advance by a calibration apparatus (not shown) and stored in the storage part 31.

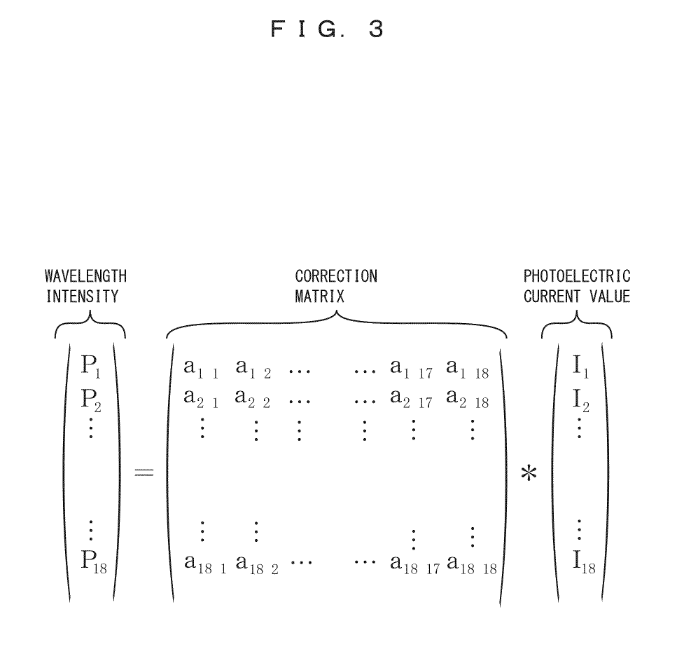

The calculation part 32 calculates the intensity distribution of the wavelengths of the respective colors based on the output values (photoelectric current values) from the 18 light-receiving elements 25 and the correction matrix stored in the storage part 31. Specifically, as shown in FIG. 3, the calculation part 32 calculates the intensity distribution (P₁, P₂, . . . ,P₁₈) of the wavelengths of the respective colors by multiplying the correction matrix a_{i,j}(1≦i≦18, 1≦j≦18) by the column (l₁, l₂, . . . , l₁₈) of the respective photoelectric current values output from the 18 light-receiving elements 25.

As described above, in the spectroscope 1, the storage part 31 stores the correction matrix in advance, and the 18 light-receiving elements 25 receive the incident light (inspection light) via the respective filtering portions 28, respectively, and output the photoelectric current values to the control unit 17. Then, the calculation part 32 calculates the wavelength intensities of the respective 18 colors based on the respective photoelectric current values output from the 18 light-receiving elements 25 and the correction matrix stored in the storage part 31. That is, the spectroscope 1 measures the intensity distribution of the respective wavelengths.

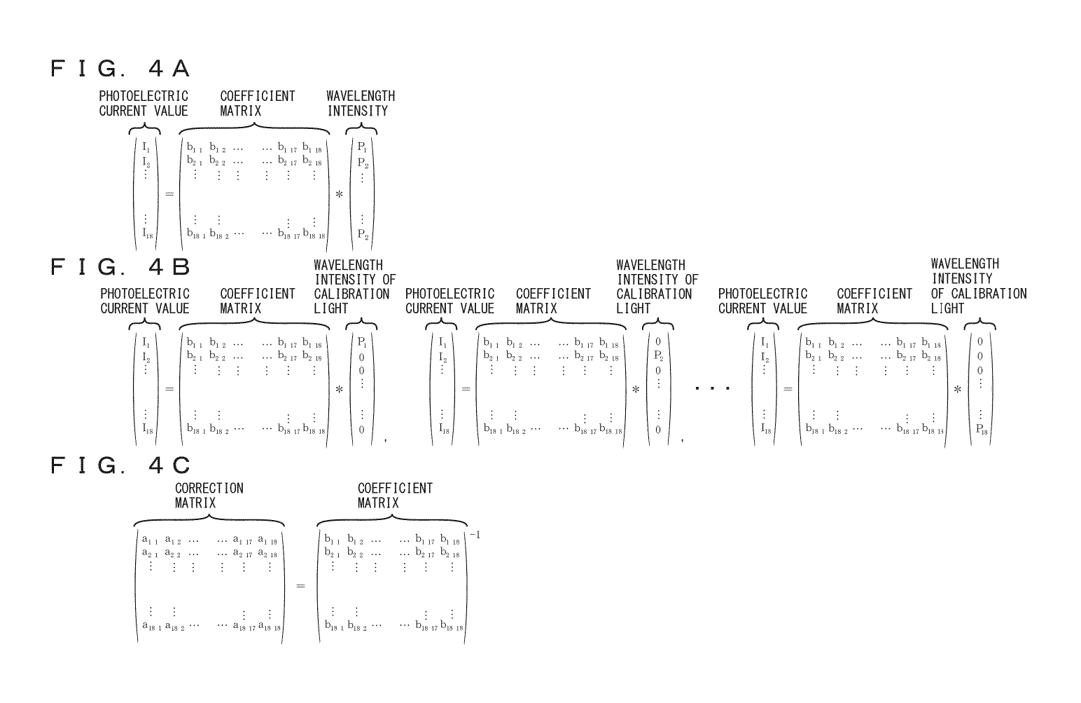

Here, the calibration processing of the spectroscope 1 will be described. The calibration processing is performed in such a way that the correction matrix of the spectroscope 1 is generated and stored in the storage part 31 of the spectroscope 1. Specifically, first, 18 types of calibration light having different specific intensity distributions (e.g., monochromatic light having the wavelengths of the respective 18 colors described above) is generated and caused to be separately incident on the spectroscope 1 to obtain the respective output values (photoelectric current values) of the 18 light-receiving elements 25 at the incident of the light. Then, transmission coefficients for the respective filtering portions 28 and the respective 18 colors are calculated based on the respective photoelectric current values and the intensity distributions of the respective calibration light to be used as a coefficient matrix bᵢⱼ(1≦i≦18, 1≦j≦18) (FIG. 4A). That is, with the respective incident calibration light, respective determinants shown in FIG. 4B are obtained. Based on the respective determinants, the respective columns of the coefficient matrix can be calculated from the respective photoelectric current values l₁, l₂, . . . , l₁₈ and the wavelength intensities Pᵢ of the respective calibration light. Then, the calculated coefficient matrix bᵢⱼ is converted into an inverse matrix to calculate a correction matrix aᵢⱼ (FIG. 4C). The calculated correction matrix is stored in the storage part 31 to complete the calibration processing.

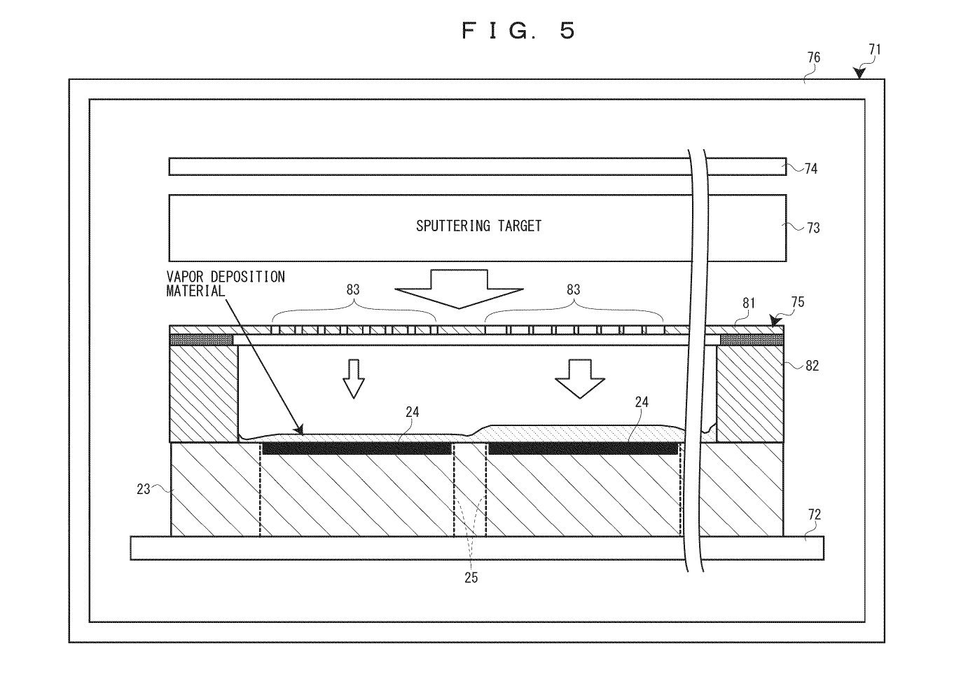

Next, with reference to FIG. 5, the manufacturing apparatus and the manufacturing method for the variable transmission wavelength interference filter 16 will be described. The manufacturing apparatus (hereinafter referred to as a filter manufacturing apparatus 71) for the variable transmission wavelength interference filter 16 represents a sputtering apparatus that uses the light-receiving element array 15 as a workpiece and forms the dielectric multi-layer film 16a on the workpiece by sputtering. In addition, with a simple configuration, the filter manufacturing apparatus 71 is capable of easily manufacturing the dielectric multi-layer film 16a having different film thicknesses at the respective positions thereof by the use of a prescribed masking member 75.

As shown in FIG. 5, the filter manufacturing apparatus 71 includes a setting table 72 on which the light-receiving element array 15 is set, a sputtering target (source for radiating a vapor deposition material) 73 disposed opposing the setting table 72, a magnet 74 disposed on the back surface side of the sputtering target 73, the masking member 75 interposed between the light-receiving element array 15 and the sputtering target 73, and a vacuum chamber 76 that accommodates the constituents described above. The masking member 75 is fixed and arranged on (the front surface of) the set light-receiving element array 15 in its positioned state and thus interposed between the light-receiving element array 15 and the sputtering target 73. The masking member 75 is attached onto the light-receiving element array 15 by, for example, temporary crimping so as to be detachable.

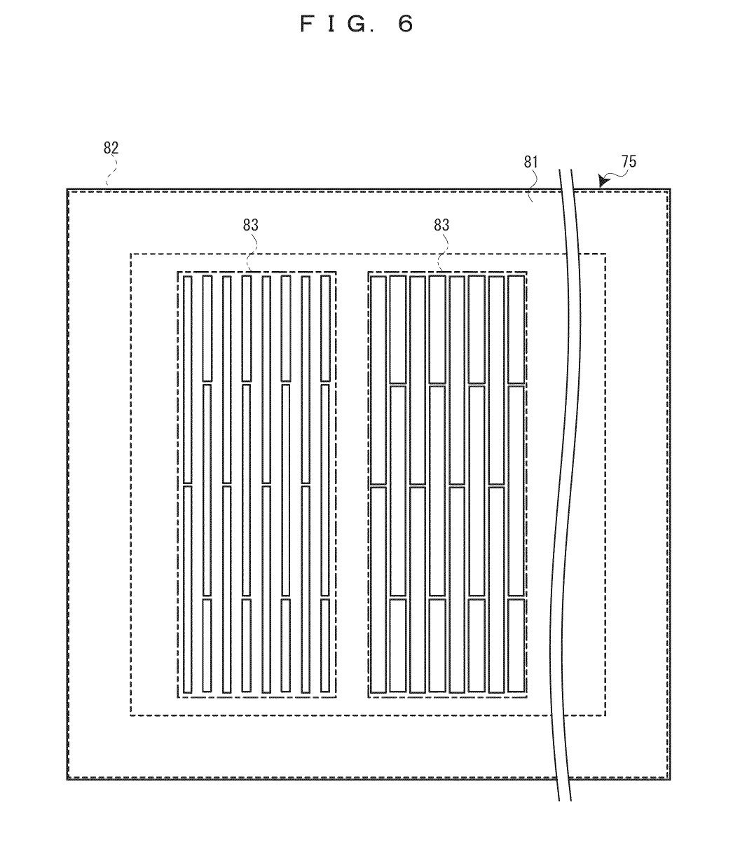

As shown in FIGS. 5 and 6, the masking member 75 includes a masking main body 81 that serves as a shielding portion and a spacer 82 that is joined to the masking main body 81 and separates the light-receiving element array 15 and the masking main body 81 from each other by a prescribed separation distance H. The masking main body 81 has opening portions 83 having different opening ratios at the positions thereof corresponding to the respective filtering portions 28 (respective light-receiving elements 25). The opening ratios of the respective opening portions 83 represent ratios at which the vapor deposition material radiated from the sputtering target 73 is shielded. Thus, the deposition amount of the vapor deposition material at the respective positions of the light-receiving element array 15 is adjusted, and the film thicknesses of the respective filtering portions 28 are controlled. By the control of the film thicknesses, the transmission characteristics of the respective filtering portions 28 on the respective light-receiving elements 25 are determined. For this reason, the opening ratios of the respective opening portions 83 are designed so as to suit the desired transmission characteristics of the respective filtering portions 28.

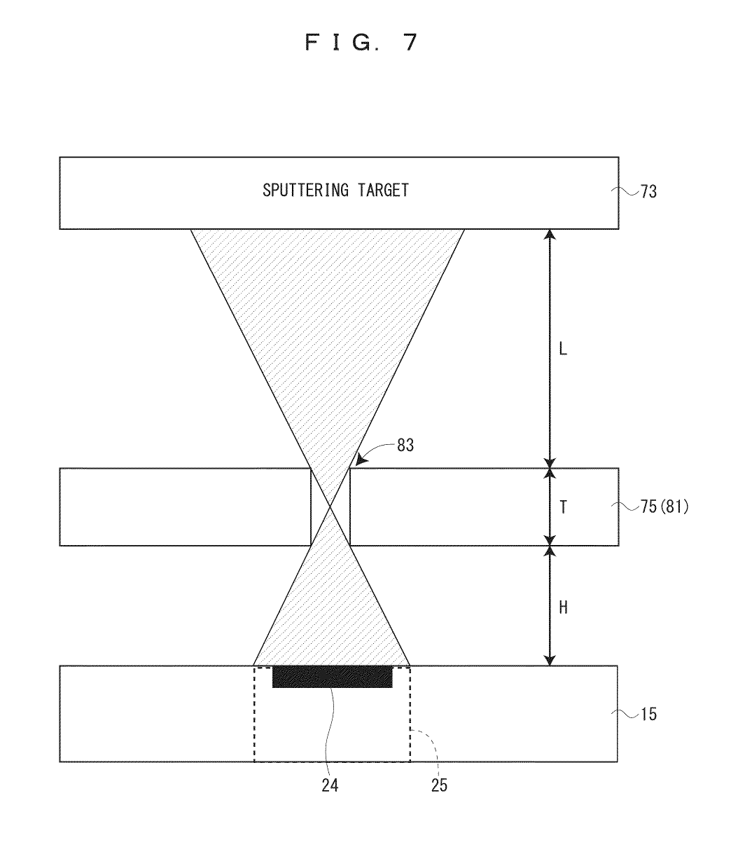

In addition, as shown in FIG. 7, a plate thickness T of the masking main body 81, a separation distance L between the sputtering target 73 and the masking main body 81, and a separation distance H between the masking main body 81 and the light-receiving element array 15 have an impact on the reaching amount and the reaching range of the vapor deposition material radiated from the sputtering target 73. That is, the plate thickness T, the separation distance L, and the separation distance H have an impact on the deposition amount of the vapor deposition material over the entire light-receiving element array 15. For this reason, the plate thickness T of the masking main body 81 and the height of the spacer 82 are designed based on the desired deposition amount, i.e., the desired film thickness of the vapor deposition material.

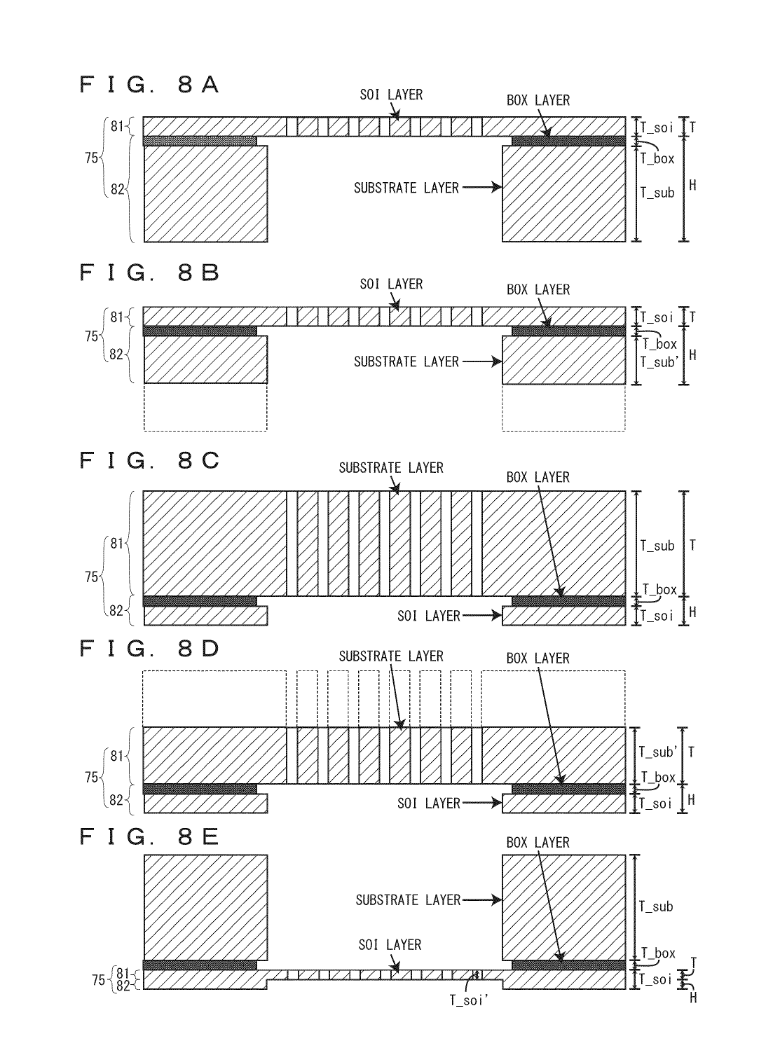

Note that in the example of FIG. 5, the masking main body 81 is made of the SOI layer of a SOI (Silicon On Insulator) wafer, and the spacer 82 is made of the substrate layer of a SOI wafer and a BOX layer. Therefore, when the thickness of the SOI layer is represented as “T_soi,” the thickness of the substrate layer is represented as “T_sub,” and the thickness of the BOX layer is represented as “T_box,” the plate thickness T of the masking main body 81 and the separation distance H between the masking main body 81 and the light-receiving element array 15 are represented by the relationships T=T_soi and H=T_box+T_sub, respectively (see FIG. 8A). As described above, the masking main body 81 and the spacer 82 are made of a SOI wafer. Therefore, the masking member 75 can be easily manufactured.

Note that besides the configuration shown in the example of FIG. 5 and FIG. 8A, the spacer 82 may be made of a BOX layer and a substrate layer thinned by back grinding or the like as shown in, for example, FIG. 8B. In this case, when the thickness of the thinned substrate layer is represented as “T_sub',” the plate thickness T of the masking main body 81 and the separation distance H between the masking main body 81 and the light-receiving element array 15 are represented by the relationships T=T_soi and H=T_box+T_sub', respectively.

In addition, as shown in, for example, FIG. 8C, the masking main body 81 may be made of a substrate layer, and the spacer 82 may be made of a SOI layer and a BOX layer. In this case, the plate thickness T of the masking main body 81 and the separation distance H between the masking main body 81 and the light-receiving element array 15 are represented by the relationships T=T_sub and H=T_box+T_soi, respectively.

Moreover, as shown in, for example, FIG. 8D, the masking main body 81 may be made of a substrate layer thinned by back grinding or the like, and the spacer 82 may be made of a SOI layer and a BOX layer. In this case, the plate thickness T of the masking main body 81 and the separation distance H between the masking main body 81 and the light-receiving element array 15 are represented by the relationships T=T_sub' and H=T_box+T_soi, respectively.

Moreover, as shown in, for example, FIG. 8E, the masking main body 81 and the spacer 82 may be made of a SOI layer. Specifically, the SOI layer is recessed to be thinned at the central area thereof so as to make the upper half portion of the SOI layer serve as the masking main body 81 and the lower half portion thereof serve as the spacer 82. In this case, when the thickness of the thinned portion of the SOI layer is represented as “T_soi',” the plate thickness T of the masking main body 81 and the separation distance H between the masking main body 81 and the light-receiving element array 15 are represented by the relationships T=T_soi' and H=T_soi−T_soi', respectively.

Next, an operation for manufacturing the variable transmission wavelength interference filter 16 will be described. The operation for manufacturing the variable transmission wavelength interference filter 16 is performed in such a way that the dielectric multi-layer film 16a is vapor-deposited by sputtering processing on the light-receiving element array 15 via the masking member 75 in a state in which the masking member 75 is fixed and arranged on the light-receiving element array 15.

Specifically, first, the vacuum chamber 76 is brought into a vacuum state, and an Ar gas (argon gas) serving as inert gas is introduced into the vacuum chamber 76. After that, the Ar gas is converted into plasma, and the ionized Ar ion is caused to collide with the sputtering target 73 by the magnet 74. By the collision of the Ar ion, the atoms (vapor deposition material) of the sputtering target 73 are radiated. Then, when the radiated vapor deposition material reaches the light-receiving element array 15 via the masking member 75, the vapor deposition material is deposited on the light-receiving element array 15 (vapor deposition).

At this time, the radiated vapor deposition material is partially shielded by the masking member 75 and deposited. However, since the opening ratios of the respective opening portions 83 are different from each other, the vapor deposition material is shielded by the masking member 75 at different shielding ratios and deposited on the respective light-receiving elements 25. That is, on the light-receiving elements 25, the deposition film is formed to be thicker at the opening portions 83 having larger opening ratios and formed to be thinner at the opening portions 83 having smaller opening ratios. As a result, the vapor deposition material having different film thicknesses is deposited on the respective light-receiving elements 25. This results in a difference in the film thicknesses between the respective filtering portions 28.

The sputtering processing is alternately repeatedly performed using high refractive materials and low refractive materials, whereby the stepped dielectric multi-layer film 16a as shown in FIG. 2 is deposited to form the respective filtering portions 28. Thus, the operation for manufacturing the variable transmission wavelength interference filter 16 is completed.

According to the configuration described above, the masking member 75 having different opening ratios at the positions thereof corresponding to the respective filtering portions 28 is used, and the dielectric multi-layer film 16a is vapor-deposited via the masking member 75. Therefore, the dielectric multi-layer film 16a having different film thicknesses at the respective positions thereof can be formed. Thus, the dielectric multi-layer film 16a can be formed with the simple configuration free from a driving unit and a control unit. In addition, the dielectric multi-layer film 16a can be easily formed only by vapor deposition in a state in which the masking member 75 is disposed. Moreover, the masking member 75 may be reused by washing.

Further, the masking member 75 is configured to have the masking main body 81 and the spacer 82 and configured be fixed and arranged on the light-receiving element array 15. Therefore, a specific structure (e.g., supporting member) for disposing the masking member 75 is not required, and the dielectric multi-layer film 16a can be formed with the simpler configuration.

Note that in the embodiment, the masking member 75 is configured to be fixed and arranged on the light-receiving element array 15 (workpiece). However, the masking member 75 may be configured to be attached to the side of the sputtering target 73. Further, the masking member 75 may be configured to be supported by a separate supporting member and interposed between the sputtering target 73 and the light-receiving element array 15.

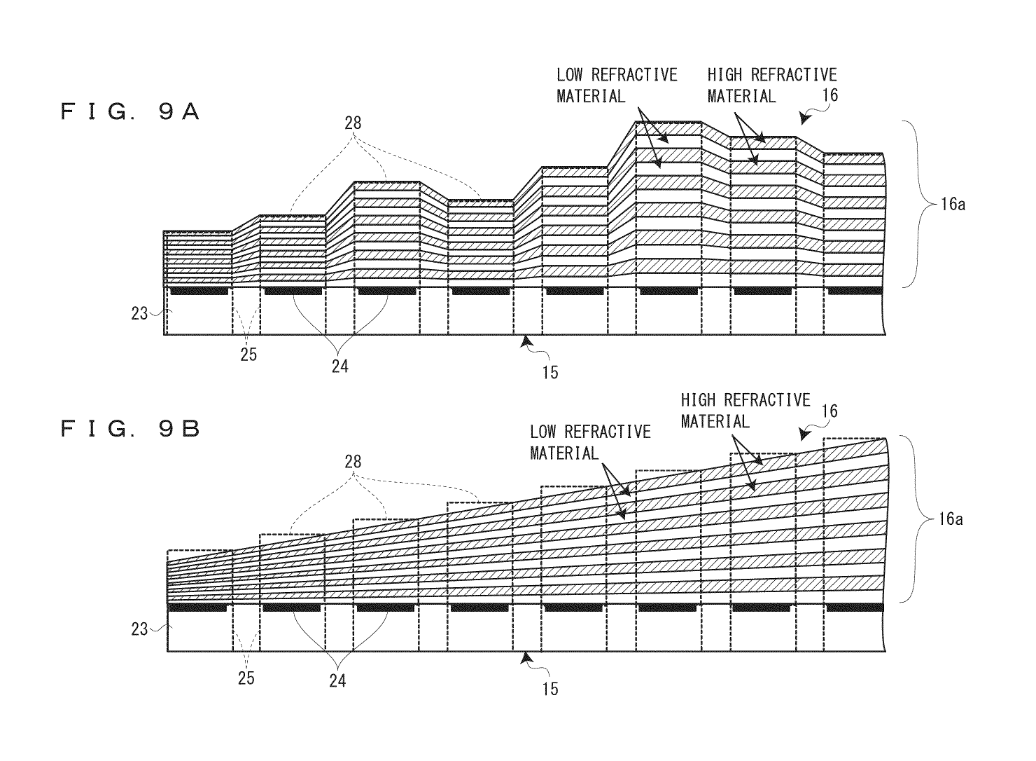

In addition, in the embodiment, the dielectric multi-layer film 16a is formed to be gradually thicker toward the arrangement direction of the light-receiving elements 25. That is, the dielectric multi-layer film 16a is configured such that the film thicknesses of the respective filtering portions 28 become larger in an order in which the respective filtering portions 28 are arranged. However, any other configurations may be employed so long as the film thicknesses of the respective filtering portions 28 are each uniform. As shown in, for example, FIG. 9A, a configuration may be employed in which the film thicknesses of the filtering portions 28 are arbitrarily set irrespective of the arrangement order of the respective filtering portions 28. That is, the configuration may be such that the filtering portions 28 having desired transmission characteristics are formed in random order. Further, as shown in FIG. 9B, a configuration may be employed in which the thickness of the dielectric multi-layer film 16a is formed by the manufacturing operation described above so as to be upwardly gradually thicker toward the arrangement direction of the light-receiving elements 25.

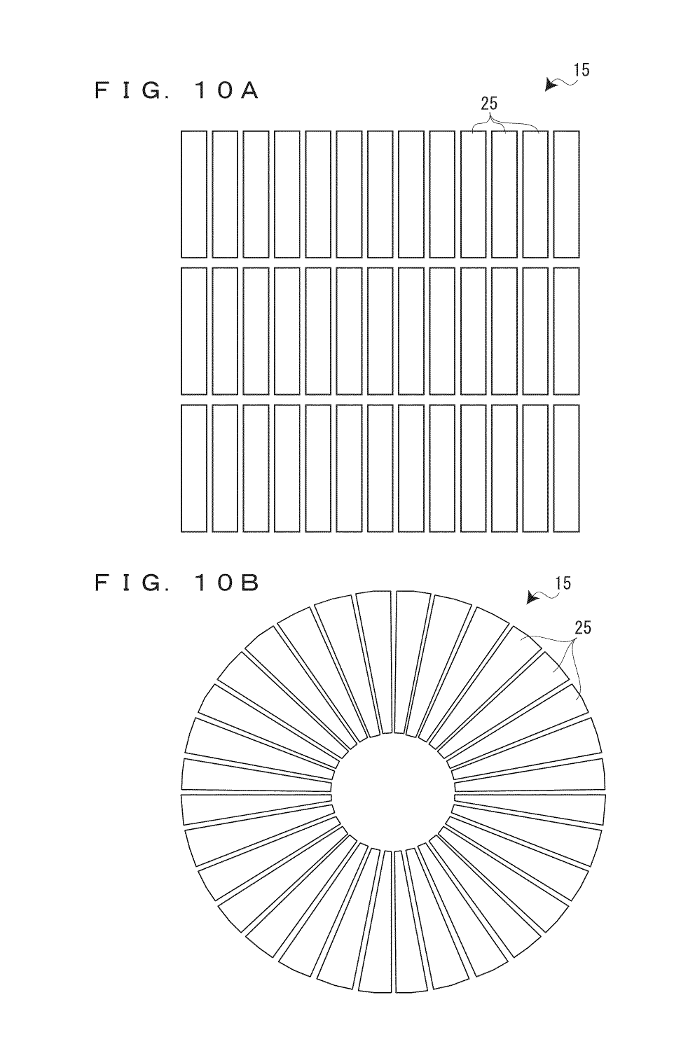

Moreover, in the embodiment, the plurality of light-receiving elements 25 is configured to be disposed side by side (in parallel). However, any other configurations may be employed. As shown in, for example, FIG. 10A, a configuration may be employed in which the plurality of light-receiving elements 25 is disposed in matrix form. Alternatively, as shown in, for example, FIG. 10B, a configuration may be employed in which the plurality of light-receiving elements 25 is disposed in ring form. The configurations described above are such that the dielectric multi-layer film 16a is formed so as to suit the arrangements of the plurality of light-receiving elements 25. That is, the configurations are such that the plurality of filtering portions 28 is formed in matrix and ring form so as to suit the arrangements of the plurality of light-receiving elements 25.

Furthermore, in the embodiment, the dielectric multi-layer film 16a is configured to be vapor-deposited by sputtering. However, a configuration may be employed in which the dielectric multi-layer film 16 is vapor-deposited by deposition.

### REFERENCE NUMERALS

15: light-receiving element array

16: variable transmission wavelength interference filter

16a: dielectric multi-layer film

28: filtering portion

73: sputtering target

75: masking member

81: masking main body

82: spacer

1-4. (canceled)

5. A method for manufacturing an optical filter constituting a plurality of filtering portions, the method comprising:
arranging a masking member on a workpiece and interposing the masking member between a source for radiating a vapor deposition material and the workpiece, the masking member having a different opening ratios at positions thereof corresponding to the respective filtering portions and having a masking main body and a spacer that separates the masking main body and the workpiece from each other; and
vapor-depositing a filtering layer on the workpiece via the masking member.

6. The method for manufacturing the optical filter according to claim 5, wherein
the spacer and the masking main body are made of a SOI wafer.

7. The method for manufacturing the optical filter according to claim 5, wherein
the filtering layer is vapor-deposited by sputtering.

8. A method for manufacturing an optical filter constituting a plurality of filtering portions which is formed on a workpiece having a plurality of light-receiving portions that receive an incident light passing through the filtering portions respectively, the method comprising:
vapor-depositing a filtering layer on the workpiece via the masking member being interposed between a source for radiating a vapor deposition material and the workpiece and has different opening ratios at positions thereof corresponding to the respective filtering portions.
